(19) United States
(12) Patent Application Publication
(10) Pub. No.: US 2005/0116866 A1
(43) Pub. Date: Jun. 2, 2005

(54) Simple gain testing method

(76) Inventors: Hsien-Chu Lin, Tu-Chen (TW); Chen-Ta Hung, Tu-Chen (TW)

Correspondence Address: WEI TE CHUNG;FOXCONN INTERNATIONAL, INC., 1650 MEMOREX DRIVE, SANTA CLARA, CA, 95050, US

(21) Appl. No.: 10/994,079

(22) Filed: Nov. 19, 2004

(30) Foreign Application Priority Data
Nov. 27, 2003 (TW) 92133312

(51) Int. Cl. G01R 29/10

(52) U.S. Cl. 343/703

(57) ABSTRACT

A simple gain testing method includes preparing a network analyzer (1) including an output port (10) and an input port (11) and preparing a reference antenna (2), a non-metal box (5) and a testing antenna (3), connecting the reference antenna with the output port and connecting the testing antenna with the input port, putting the reference antenna and the testing antenna into the non-metal box, and analyzing a gain result by the network analyzer.

### BACKGROUND OF THE INVENTION

1. Field of the Invention

The present invention concerns generally the practical field of a testing method, and especially concerns a method of testing an antenna's performance.

2. Description of the Prior Art

In order to satisfy a wireless communication system, an antenna's performance must be evaluated. Typical metrics used in evaluating an antenna includes the input impedance, polarization, radiation efficiency, directivity, gain and radiation pattern, and so on. Among these parameters, some are easy to be tested, and some are almost impossible to be tested on line in plant. So it is difficult to test all of these parameters to indicate an antenna's performance.

A common method of testing an antenna in prior art is to test the input impedance indicating an impedance matching. The impedance matching between an antenna and a transmission line is usually expressed in terms of the Voltage Standing Wave Ratio (VSWR). The VSWR is the ratio of the maximum to minimum voltage of a standing wave along a transmission line. The VSWR is an important factor that affects the performance characteristics of the antenna and provides important information about how the antenna will operate. If there is a mismatch of impedance along a circuit including a transmitter or receiver, a transmission line and an antenna, there will be an inefficient transfer of energy either from the transmitter via the transmission line to the remote wireless receiver, or from the remote wireless transmitter via the antenna and the transmission line into the receiver. Therefore, using the VSWR to indicate an antenna's performance is very popular in use.

In practical use, the VSWR of an antenna is tested by a network analyzer. However, the VSWR can only present the ratio of the maximum to minimum voltage, but not considering the unexpected loss. Typically, as is known in prior art, there inevitably exists signal loss due to coupling, as well as an insertion loss due to a matching circuit. Besides, there also exists a cable loss (about 3 dB) and a connector loss (about 1 dB) which both adversely affect the antenna's performance. Because of these losses, the transmitting or receiving power of the antenna is reduced. That is, though the VSWR of the antenna is acceptable, the antenna's performance is not good. Furthermore, when the loss on transmission line is too large, only a part of retuning energy can go back to the network analyzer. Thus the testing result of the VSWR is sometimes not very accurate.

Herein, an more accurate method of testing the gain of the antenna is proposed. The gain is a measure of the ability to concentrate in a particular direction the net power accepted by the antenna from the connected transmitter. Antenna gain is independent of reflection losses resulting from impedance mismatch. Thus, if the antenna gain meets the requirement, we can come to a conclusion that the antenna's performance is good.

Hence, synthetically consider the factors of accuracy, a simple gain testing method of an antenna is need in art to overcome the above-mentioned disadvantages of the conventional testing method of an antenna.

### BRIEF SUMMARY OF THE INVENTION

A primary object, therefore, of the present invention is to provide a simple gain testing method.

The gain testing method comprises the steps as follows. Preparing a network analyzer comprising an output port and an input port, a dipole antenna as a reference antenna, a non-metal box defining a first fixture hole and a second fixture hole, and a planar inverted-F antenna as a testing antenna. Connecting the reference antenna with the output port and connecting the testing antenna with the input port. Inserting the reference antenna and the testing antenna into the non-metal box separately through the first fixture hole and the second fixture hole. Analyzing a gain result in the network analyzer. An electromagnetic wave is transmitted from the output port of the network analyzer to the reference antenna and radiated by the reference antenna. A part of the electromagnetic wave can be received by the testing antenna, and transported to the input port of the network analyzer. Then the analyzer can analyze a gain result from comparing the input and the output electromagnetic waves.

Other objects, advantages and novel features of the invention will become more apparent from the following detailed description when taken in conjunction with the accompanying drawings.

### BRIEF DESCRIPTION OF THE DRAWINGS

FIG. 1 is a schematic sketch of a simple gain testing method in accordance with a first embodiment of the present invention.

FIG. 2 is a schematic sketch of the simple gain testing method in accordance with a second embodiment of the present invention.

### DETAILED DESCRIPTION OF THE INVENTION

Reference will now be made in detail to preferred embodiments of the present invention.

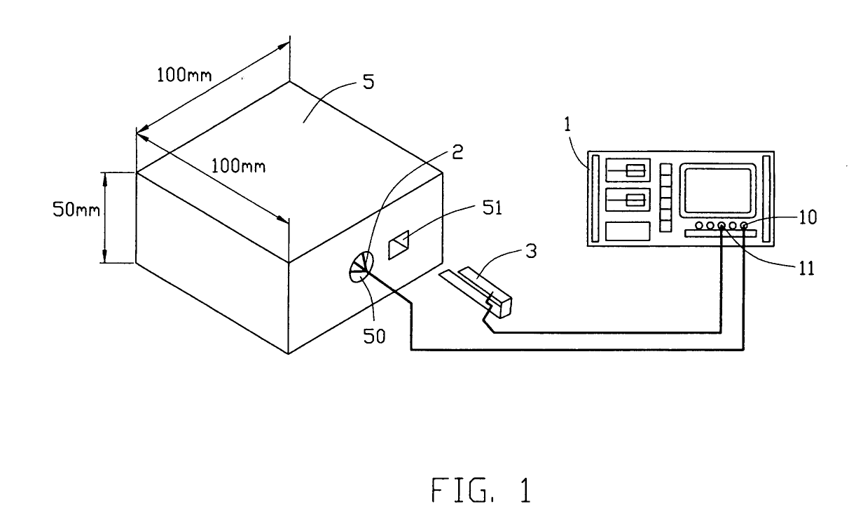

Referring to FIG. 1, a gain testing method according to a first embodiment of the present invention is provided. A network analyzer 1, a reference antenna 2, a testing antenna 3, and a non-metal box 5 are prepared. The reference antenna 2 is required to be steady, sensitive and omni-directional, whose performance is required to approach idealization. The reference antenna 2 is a dipole antenna because a dipole antenna provides an arrangement wherein the feed network does not interfere with the radiation path thereof, and in which there is minimal unwanted radiation. The testing antenna 3 can be any type of compact antennas used in an electronic device. In this first embodiment, the testing antenna 3 is a planar inverted-F antenna. The network analyzer 1 comprises an output port 10 and an input port 11. The non-metal box 5 is a hollow box and defines a first fixture hole 50 through which the reference antenna 2 is inserted into the non-metal box 5 and a second fixture hole 51 through which the testing antenna 3 is inserted into the non-metal box 5. The first and the second fixture holes 50 and 51 are defined in the same side of the non-metal box 5. The distance between the first fixture hole 50 and the second fixture hole 51 is determined by the sensitivity of the reference antenna 2. In this preferred embodiment, the distance between the first fixture hole 50 and the second fixture hole 51 is about 20-30 mm, whereby the testing antenna 3 falls into the sensitivity scope of the reference antenna 2. The non-metal box 5 can be made of plastic, wood or any other non-metal material for preventing the reference antenna 2 and the testing antenna 3 from unexpected interference. The dimensions of the non-metal box 5 are given in FIG. 1 and are in millimeter.

When testing, connecting the output port 10 with a first feed point (not labeled) of the reference antenna 2 via a first transmission line (not labeled) and connecting the input port 11 with a second feed point (not labeled) of the testing antenna 3 via a second transmission line (not labeled). Then inserting the reference antenna 2 into the non-metal box 5 through the first fixture hole 50 and inserting the testing antenna 3 into the non-metal box 5 through the second fixture hole 51.

Next, an output signal is output from the output port 10 of the network analyzer 1 and is transmitted to the reference antenna 2 via the first transmission line. When testing, a resonant frequency of the testing antenna 3 in a testing environment is a little higher than a working frequency of the antenna 3 in a practical working environment in the electronic device. So the frequency of the output signal, which is equal to the resonant frequency of the testing antenna 3, is required to be prearranged a little higher than that of the practical working frequency of the testing antenna 3. For example, if the practical working frequency band of the testing antenna 3 is 2.4-2.5 GHz, the frequency of the output signal of the network analyzer 1 can be chosen 2.5-2.8 GHz. Next, the output signal is radiated into a radiating electromagnetic wave by the reference antenna 2. A part of the radiating electromagnetic wave radiated by the reference antenna 2 can be received by the testing antenna 3. The electromagnetic wave received by the testing antenna 3 is understood as a received signal. The reference antenna 2 here is being an actuator, which gives the testing antenna 3 exciting. Then the testing antenna 3 transmits the received signal from the second feed point into the input port 11 of the network analyzer 1. The signal input to the network analyzer 1 is understood as an input signal. The network analyzer 1 can obtain an analyzing result of the gain of the testing antenna 3 by comparing the input and output signals of the network analyzer 1. In practical application, there needs to preorder a gain standard. If the gain of the testing antenna 3 meets the standard, the testing antenna 3 can be judged to be an effective antenna or an inferiority antenna. So according to the analyzing result by the network analyzer 1, the inferiority antennas can be picked out.

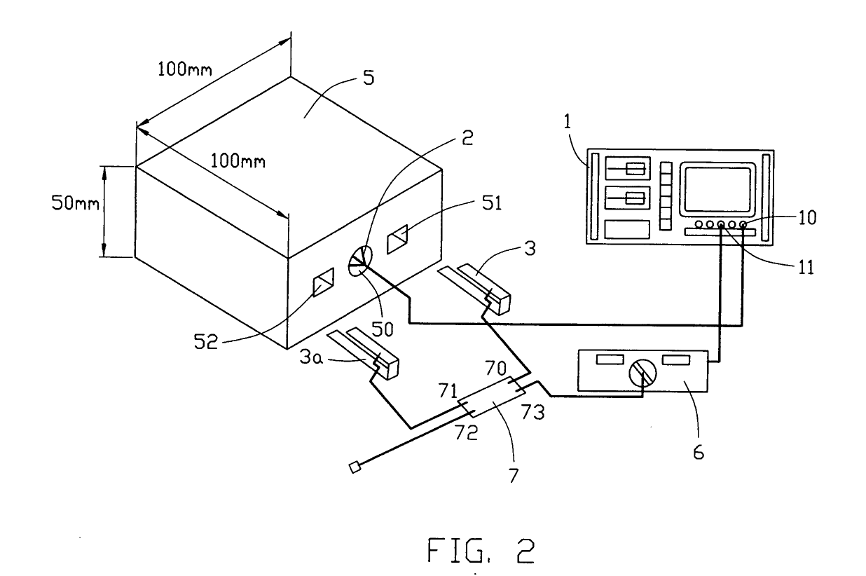

Referring to FIG. 2, a gain testing method according to a second embodiment of the present invention is provided for testing an antenna assembly. In this second embodiment, the antenna assembly comprises a first testing antenna 3, a second testing antenna 3a and a diversity board 7. The non-metal box 5 defines a third fixture hole 52 besides the first fixture hole 50 and the second fixture hole 51 for inserting the second testing antenna 3a therethrough. The diversity board 7 comprises a first pin 70 connected to the first testing antenna 3, a second pin 71 connected to the second testing antenna 3a, a third pin 72, and a switch means (not shown) connecting with the first pin 70 or the second pin 71. An adding switch controlling means 6 should be prepared before testing. The switch controlling means 6 is connected with the third pin 72 of the diversity board 7 and is provided for controlling the switch means on the diversity board 7 to connecting with one of the testing antennas 3 and 3a to be tested.

When testing, connecting the first output port 10 of the network analyzer 1 with the reference antenna 2 and connecting the second input port 11 with the switch controlling means 6. Connecting the switch controlling means 6 with the third pin 72 of the diversity board 7. Inserting the reference antenna 2 into the non-metal box 5 through the first fixture hole 50, inserting the first testing antenna 3 into the non-metal box 5 through the second fixture hole 51, and inserting the second testing antenna 3a into the non-metal box 5 through the third fixture hole 52. The reference antenna 2 is placed between the testing antennas 3 and 3a. The distance between the reference antenna 2 and each testing antenna 3 or 3a refers to the practical distance when the antenna assembly is used in the electronic device and can be properly adjusted to control the same sensibility of the radiating electromagnetic waves from the reference antenna 2 to the two testing antennas 3 and 3a. The switch controlling means 6 is provided for choosing an antenna to be tested between the first testing antenna 3 and the second testing antenna 3a. When the switch controlling means 6 is rotated to a first position (not shown), the first testing antenna 3 is switched to connect with the input port 11 of the network analyzer 1 via the diversity board 7 and the switch controlling means 6, while the second testing antenna 3a is disconnected with the input port 11. When the switch controlling means 6 is rotated to a second position (not shown), the second testing antenna 3a is switched to connect with the input port 11 of the network analyzer 1 via the diversity board 7 and the switch controlling means 6, while the first testing antenna 3 is disconnected with the input port 11. The other testing steps in the second embodiment are the same as those is disclosed in the first embodiment.

In other embodiments, the antenna assembly may comprise more than two testing antennas. The dimensions of the non-metal box and the numbers, shapes and sizes of the fixture holes can be designed according to the antenna assembly.

It is to be understood that the embodiments and variations shown and described herein are merely illustrative of the principles of this invention and that various modifications may be implemented by those skilled in the art without departing from the scope and spirit of the invention. Especially, it is to be understood that the present invention is not in any way restricted to the mentioned forms or assemblies of the illustrated devices. And even if the described embodiments have concerned inverted-F antennas, it is clear that the invention can be applied with any kind of compact antennas.

1. A gain testing method, comprising steps of:
preparing a reference antenna, a testing antenna and a network analyzer, the network analyzer comprising an input port connecting with the testing antenna and an output port connecting with the reference antenna;
outputting an output signal from the network analyzer to the reference antenna;
radiating the output signal received by the reference antenna to the testing antenna;
receiving a received signal transmitted from the reference antenna by the testing antenna and transporting the received signal into the network analyzer; and
comparing the output signal and the received signal in the network analyzer.

2. The gain testing method as claimed in claim 1, wherein the preparing step provides an omni-direction antenna as the reference antenna.

3. The gain testing method as claimed in claim 1, wherein the preparing step provides a dipole antenna as the reference antenna.

4. The gain testing method as claimed in claim 1, wherein the preparing step provides the reference antenna as an actuator to excite the testing antenna.

5. The gain testing method as claimed in claim 1, wherein the preparing step provides an inverted-F antenna as the testing antenna.

6. The gain testing method as claimed in claim 1, wherein the preparing step further comprises preparing a non-metal box for receiving the reference antenna and the testing antenna.

7. The gain testing method as claimed in claim 6, wherein the non-metal box defines a fixture hole for inserting the reference antenna and the testing antenna therethrough.

8. The gain testing method as claimed in claim 1, wherein the preparing step provides an antenna assembly as the testing antenna, the antenna assembly comprising a first testing antenna and a second testing antenna.

9. The gain testing method as claimed in claim 8, wherein the antenna assembly comprises a diversity board having a first pin connecting with the first testing antenna and a second pin connecting with the second testing antenna.

10. The gain testing method as claimed in claim 9, wherein the preparing step further comprises preparing a switch controlling means connecting with the diversity board and controlling the diversity board to electrically connect one of the first and the second testing antennas with the network analyzer.

11. The gain testing method as claimed in claim 8, wherein the preparing step comprises providing the reference antenna between the first and the second testing antennas.

12. A gain testing method for a testing antenna comprising using a reference antenna to radiate a signal based upon a standard output signal, transporting a received signal of the testing antenna derived from said reference antenna to an analyzer, and comparing the standard output signal and the transported received signal.
